(19) United States
(12) Patent Application Publication
(10) Pub. No.: US 2006/0154449 A1
(43) Pub. Date: Jul. 13, 2006

(54) Method of laser processing a wafer

(75) Inventor: Satoshi Kobayashi, Tokyo (JP)

Correspondence Address: SMITH, GAMBRELL & RUSSELL, LLP, 1850 M STREET, N.W., SUITE 800, WASHINGTON, DC, 20036, US

(73) Assignee: Disco Corporation

(21) Appl. No.: 11/329,169

(22) Filed: Jan. 11, 2006

(30) Foreign Application Priority Data
Jan. 13, 2005 (JP) 2005-006060

(51) Int. Cl. H01L 21/78; H01L 21/301; H01L 21/46

(52) U.S. Cl. 438/462

(57) ABSTRACT

A method of laser processing a wafer having a plurality of devices that are composed of a laminate layer laminated on the front surface of a substrate, along a plurality of streets for sectioning the devices, comprising a first groove forming step for applying a first laser beam having absorptivity for the wafer along the streets of the wafer at predetermined intervals to form two grooves for preventing the flaking of a layer, which divide the laminate layer; and a second groove forming step for applying a second laser beam having absorptivity for the wafer to the center between the two grooves for preventing the flaking of a layer, which have been formed along the streets of the wafer by the first groove forming step, along the streets of the wafer to form a dividing groove having a predetermined depth in the laminate layer and the substrate.

### FIELD OF THE INVENTION

The present invention relates to a method of laser processing a wafer having a plurality of devices, which are composed of a laminate layer laminated on the front surface of a substrate along streets formed on the front surface of the wafer.

### DESCRIPTION OF THE PRIOR ART

As is known to people of ordinary skill in the art, an optical device wafer having a plurality of optical devices which are composed of a laminate layer of silicon oxide (SiO₂) and the like that discriminates a specific wavelength, and formed in a matrix on the front surface of a substrate made of quartz, glass or the like is manufactured in the production process of an optical device. The above optical devices are sectioned by dividing lines called “streets” in the thus-formed optical device wafer, and individual optical devices are manufactured by dividing this optical device wafer along the streets.

Dividing along the streets of the above optical device wafer is generally carried out by using a cutting machine called “dicer”. This cutting machine comprises a chuck table for holding an optical device wafer as a workpiece, a cutting means for cutting the workpiece held on the chuck table, and a moving means for moving the chuck table and the cutting means relative to each other. The cutting means comprises a rotary spindle that is rotated at a high speed and a cutting blade mounted on the spindle. The cutting blade comprises a disk-like base and an annular cutting edge, which is mounted on the side wall outer peripheral portion of the base and formed by fixing diamond abrasive grains having a diameter of about 3 μm to the base by electroforming.

Since the optical device wafer is made of a material having extremely high hardness, it cannot be cut with the cutting blade at a rate of 10 mm/sec or less, thereby making a problem in respect of productivity. Further, a cutting blade having a thickness of about 250 μm must be used to cut the optical device wafer, chippings are large in size and hence, the width of each street must be made 300 μm or more, thereby causing other problems in respect of productivity.

Meanwhile, as a means of dividing a plate-like workpiece such as a semiconductor wafer, JP-A 10-305420 discloses a method in which a pulse laser beam is applied along streets formed on a workpiece to form grooves and the workpiece is divided along the above grooves by a mechanical breaking apparatus.

According to this dividing method, the processing speed for forming grooves can be made several times faster than the cutting speed when the cutting blade is used.

To divide the wafer along the grooves easily by mechanical breaking after laser processing, the grooves must be formed deep. To form the deep grooves without reducing the laser processing speed, a high-output laser beam must be applied. When a high-output laser beam is applied to the wafer, however, the laminate layer may flake off about 100 to 200 μm on one side by an impact made by the application of the laser beam, thereby damaging devices.

### SUMMARY OF THE INVENTION

It is an object of the present invention to provide a wafer laser processing method capable of forming grooves deep enough to facilitate division by mechanical breaking while the flaking of a laminate layer is suppressed within a certain range.

To attain the above object, according to the present invention, there is provided a method of laser processing a wafer having a plurality of devices that are composed of a laminate layer laminated on the front surface of a substrate, along a plurality of streets for sectioning the devices, comprising:

a first groove forming step for applying a first laser beam having absorptivity for the wafer along the streets of the wafer at predetermined intervals to form two grooves for preventing the flaking of a layer, which divide the laminate layer; and

a second groove forming step for applying a second laser beam having absorptivity for the wafer to the center between the two grooves for preventing the flaking of a layer, which have been formed along the streets of the wafer by the first groove forming step, along the streets of the wafer to form a dividing groove having a predetermined depth in the laminate layer and the substrate.

In the wafer laser processing method according to the present invention, since the second groove forming step for forming a dividing groove having a predetermined depth in the laminate layer and the substrate at the center between two grooves for preventing the flaking of a layer is carried out after the two grooves for preventing the flaking of a layer, which divide the laminate layer, are formed along the streets of the wafer by the first groove forming step, the laminate layer in the streets is divided by the two grooves for preventing the flaking of a layer when the second groove forming step is carried out. Therefore, even if the laminate layer flakes off by the application of the second pulse laser beam, the flaking does not affect the outer sides of the two grooves, that is, the sides of the devices. Consequently, the pulse energy of the second pulse laser can be increased, and the dividing groove can be formed to a desired depth that facilitates division of the wafer.

### BRIEF DESCRIPTION OF THE DRAWINGS

FIG. 1 is a perspective view of an optical device wafer to be divided by the wafer laser processing method of the present invention;

FIG. 2 is an enlarged sectional view of the optical device wafer shown in FIG. 1;

FIG. 3 is a perspective view showing a state where the optical device wafer is supported to an annular frame through a protective tape;

FIG. 4 is a perspective view of the principal portion of a laser beam processing machine for carrying out groove forming steps in the wafer laser processing method of the present invention;

FIG. 5 is a block diagram schematically showing the constitution of the laser beam application means provided in the laser beam processing machine shown in FIG. 4;

FIG. 6 is a schematic diagram showing the focusing spot diameter of a laser beam;

FIGS. 7(a) and 7(b) are explanatory diagrams showing a first groove forming step in the wafer laser processing method of the present invention;

FIG. 8 is an enlarged sectional view of the principal portion of the optical device wafer having grooves for preventing the flaking of a layer, which are formed in the street by the first groove forming step shown in FIGS. 7(a) and 7(b);

FIGS. 9(a) and 9(b) are explanatory diagrams showing a second groove forming step in the wafer laser processing method of the present invention; and

FIG. 10 is an enlarged sectional view of the principal portion of the optical device wafer showing grooves for preventing the flaking of a layer and a dividing groove, which are formed in the street by carrying out the first groove forming step and the second groove forming step in the wafer laser processing method of the present invention.

### DETAILED DESCRIPTION OF THE PREFERRED EMBODIMENTS

The wafer laser processing method of the present invention will be described in more detail hereinunder with reference to the accompanying drawings.

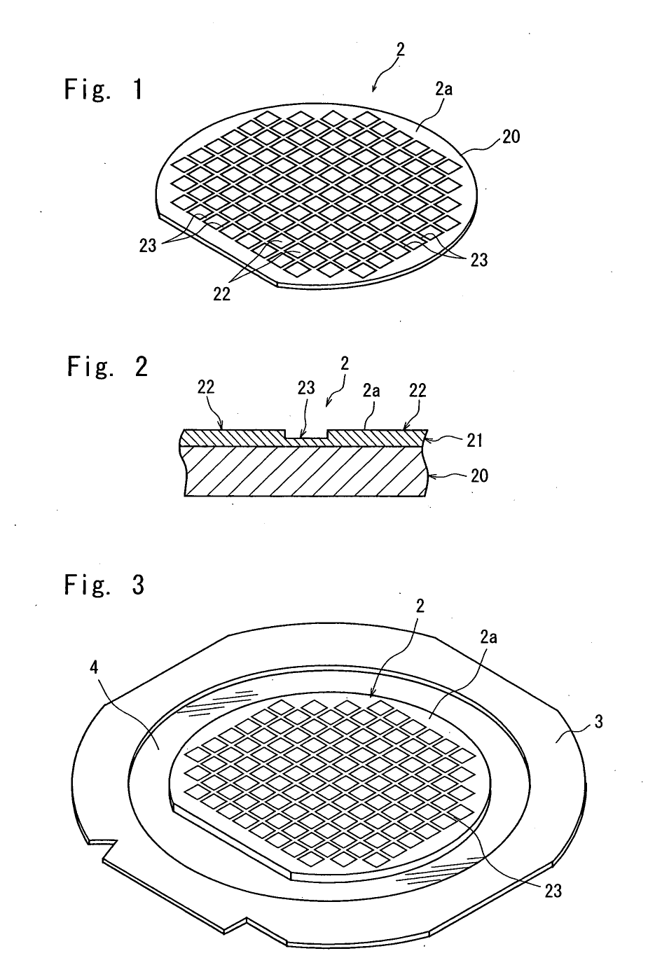

FIG. 1 is a perspective view of an optical device wafer to be divided into individual chips by the wafer laser processing method of the present invention, and FIG. 2 is an enlarged sectional view of the principal portion of the optical device wafer shown in FIG. 1. The optical device wafer 2 shown in FIG. 1 and FIG. 2 has a plurality of devices 22 which are composed of a laminate layer 21 comprising a layer having a wavelength discriminating filter function to transmit only light having a specific wavelength or a specific wavelength range and reflect light having other wavelengths and formed in a matrix on the front surface of a substrate 20 made of quartz, borosilicate glass or the like. The devices 22 are sectioned by streets 23 formed in a lattice pattern. In the illustrated embodiment, laminates forming the laminate layer 21 are made of silicon oxide (SiO₂), titanium oxide (TiO₂) and magnesium fluoride (MgF₂).

To divide the above optical device wafer 2 along the streets 23, the optical device wafer 2 is put on the surface of a protective tape 4 mounted on an annular frame 3, as shown in FIG. 3. At this point, the optical device wafer 2 is put on the protective tape 4 in such a manner that the front surface 2a faces up.

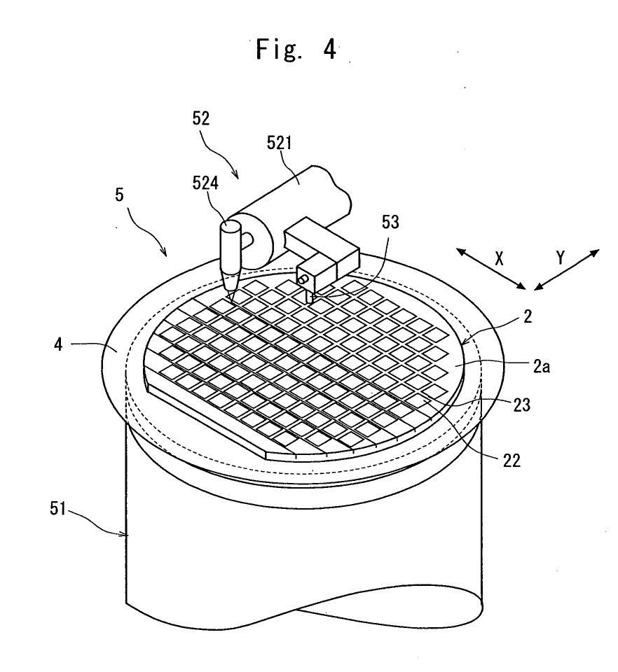

Next comes a first groove forming step for forming two grooves for preventing the flaking of a layer to divide the laminate layer 21 by applying a first laser beam having absorptivity for the optical device wafer 2 along the streets 23 of the optical device wafer 2 at predetermined intervals. This first groove forming step is carried out by using a laser beam processing machine 5 shown in FIGS. 4 to 6. The laser beam processing machine 5 shown in FIGS. 4 to 6 comprises a chuck table 51 for holding a workpiece and a laser beam application means 52 for applying a laser beam to the workpiece held on the chuck table 51. The chuck table 51 is constituted so as to suction-hold the workpiece and is designed to be moved in a processing-feed direction indicated by an arrow X in FIG. 4 by a processing-feed mechanism (not shown) and in an indexing-feed direction indicated by an arrow Y by an indexing-feed mechanism that is not shown.

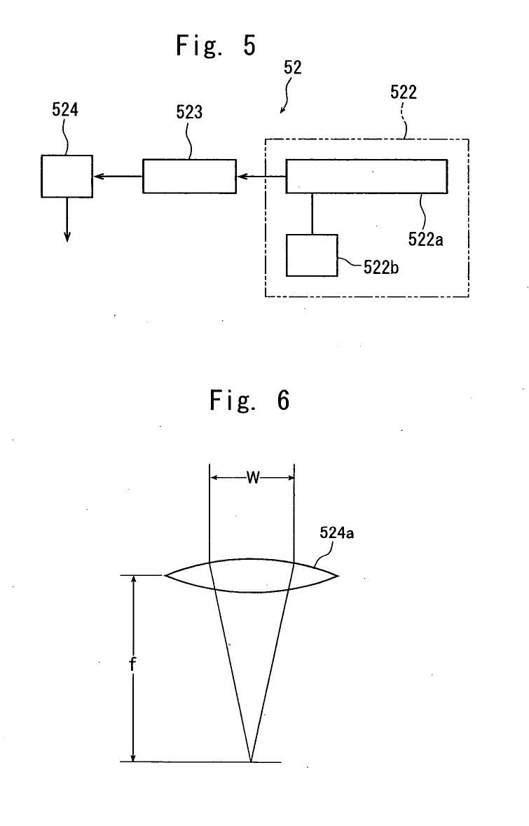

The above laser beam application means 52 has a cylindrical casing 521 arranged substantially horizontally. In the casing 521, there are installed a pulse laser beam oscillation means 522 and a transmission optical system 523, as shown in FIG. 5. The pulse laser beam oscillation means 522 comprises a pulse laser beam oscillator 522a composed of a YAG laser oscillator or YVO4 laser oscillator and a repetition frequency setting means 522b connected to the pulse laser beam oscillator 522a. The transmission optical system 523 comprises suitable optical elements such as a beam splitter, etc. A condenser 524 housing condensing lenses (not shown) constituted by a set of lenses that may be formation known per se is attached to the end of the above casing 521. A laser beam oscillated from the above pulse laser beam oscillation means 522 reaches the condenser 524 through the transmission optical system 523 and is applied to the workpiece held on the above chuck table 51 from the condenser 524 at a predetermined focusing spot diameter D. This focusing spot diameter D is defined by the expression D (μm)=4×λ×f/(π×W) (wherein λ is the wavelength (μm) of the pulse laser beam, W is the diameter (mm) of the pulse laser beam applied to an objective condenser lens 524a, and f is the focusing distance (mm) of the objective condenser lens 524a) when the pulse laser beam showing a Gaussian distribution is applied through the objective condenser lens 524a of the condenser 524, as shown in FIG. 6.

The illustrated laser beam processing machine 5 comprises an image pick-up means 53 attached to the end of the casing 521 constituting the above laser beam application means 52, as shown in FIG. 4. This image pick-up means 53 picks up an image of the workpiece held on the chuck table 51. The image pick-up means 53 is constituted by an optical system, an image pick-up device (CCD), and the like, and transmits an image signal to a control means that is not shown.

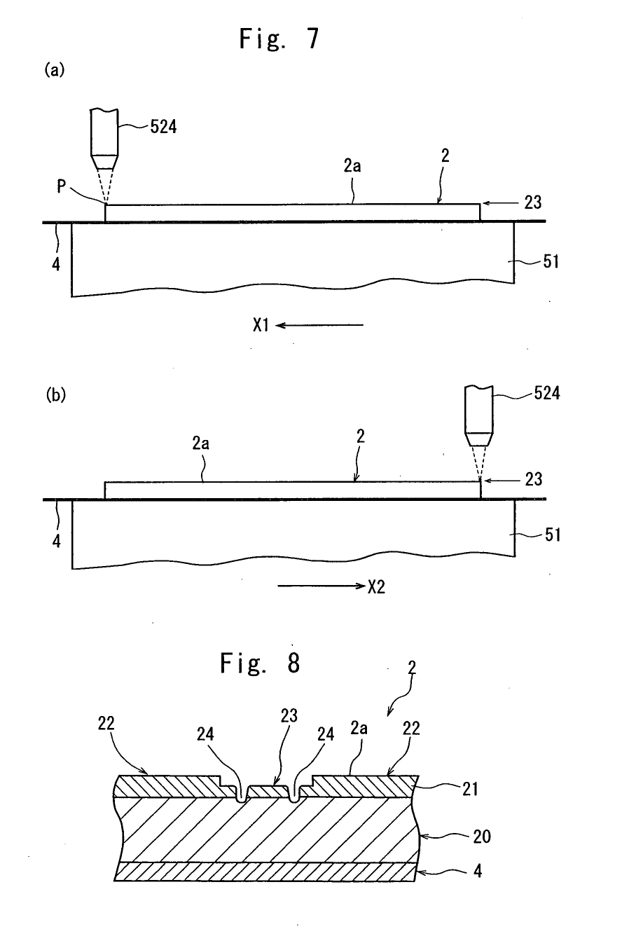

A description will be subsequently given of a first groove forming step which is carried out by using the above laser beam processing machine 5 with reference to FIG. 4, FIGS. 7(a) and 7(b) and FIG. 8.

In this first groove forming step, the optical device wafer 2 is first placed on the chuck table 51 of the laser beam processing machine 5 shown in FIG. 4, and suction-held on the chuck table 51. At this point, the optical device wafer 2 is held in such a manner that the front surface 2a faces up. In FIG. 4, the annular frame 3 onto which the protective tape 4 is mounted is not shown but it is held by a suitable frame holding means provided on the chuck table 51.

The chuck table 51 suction-holding the optical device wafer 2 as described above is brought to a position right below the image pick-up means 53 by the processing-feed mechanism that is not shown. After the chuck table 51 is positioned right below the image pick-up means 53, alignment work for detecting the area to be processed of the optical device wafer 2 is carried out by using the image pick-up means 53 and the control means that is not shown. That is, the image pick-up means 53 and the control means (not shown) carry out image processing such as pattern matching, etc. to align a street 23 formed in a predetermined direction of the optical device wafer 2 with the condenser 524 of the laser beam application means 52 for applying a laser beam along the street 23, thereby performing the alignment of a laser beam application position. The alignment of the laser beam application position is also carried out on streets 23 formed on the optical device wafer 2 in a direction perpendicular to the above predetermined direction.

After the street 23 formed on the optical device wafer 2 held on the chuck table 51 is detected and the alignment of the laser beam application position is carried out as described above, the chuck table 51 is moved to a laser beam application area where the condenser 524 of the laser beam application means 52 for applying a laser beam is located to bring the predetermined street 23 to a position right below the condenser 524 as shown in FIG. 7(a). At this point, as shown in FIG. 7(a), the optical device wafer 2 is positioned such that one end (left end in FIG. 7(a)) of the street 23 is located right below the condenser 524. The chuck table 51, that is, the optical device wafer 2 is then moved in the direction indicated by the arrow X1 in FIG. 7(a) at a predetermined processing-feed rate while a first pulse laser beam is applied from the condenser 524 of the laser beam application means 52. When the other end (right end in FIG. 7(b)) of the street 23 reaches a position right below the condenser 524 as shown in FIG. 7(b), the application of the pulse laser beam is suspended and the movement of the chuck table 51, that is, the optical device wafer 2 is stopped. In this first groove forming step, the focusing point P of the pulse laser beam is set to a position near the front surface of the street 23.

Thereafter, the chuck table 51, that is, the optical device wafer 2 is moved about 150 to 200 μm in a direction perpendicular to the sheet (indexing-feed direction). The chuck table 51, that is, the optical device wafer 2 is then moved in the direction indicated by the arrow X2 in FIG. 7(b) at a predetermined processing-feed rate while a pulse laser beam is applied from the condenser 524 of the laser beam application means 52. When the one end of the street 23 reaches the position shown in FIG. 7(a), the application of the pulse laser beam is suspended and the movement of the chuck table 51, that is, the optical device wafer 2 is stopped.

By carrying out the above first groove forming step, two grooves 24 and 24 for preventing the flaking of a layer, which are deeper than the thickness of the laminate layer 21, are formed in the street 23 of the optical device wafer 2, as shown in FIG. 8. As a result, the laminate layer 21 forming the street 23 is divided by the two grooves 24 and 24. The above first groove forming step is carried out on all the streets 23 formed on the optical device wafer 2.

The above first groove forming step is carried out under the following processing conditions, for example.
Light source of laser beam: YVO4 laser or YAG laser
Wavelength: 355 nm
Repetition frequency: 50 kHz
Pulse energy: 40 μJ
Focusing spot diameter: 10 μm
Processing-feed rate: 100 mm/sec

After the above first groove forming step is carried out on all the streets 23 formed on the optical device wafer 2, next comes a second groove forming step for forming a dividing groove having a predetermined depth in the laminate layer 21 and the substrate 20 by applying a second laser beam having absorptivity for the wafer 2 to the center between the two grooves 24 and 24 formed along the streets 23 of the optical device wafer 2 by the first groove forming step. This second groove forming step is carried out by using the laser beam processing machine 5 shown in FIGS. 4 to 6 and for example, a second laser beam having greater pulse energy than the pulse energy in the first groove forming step.

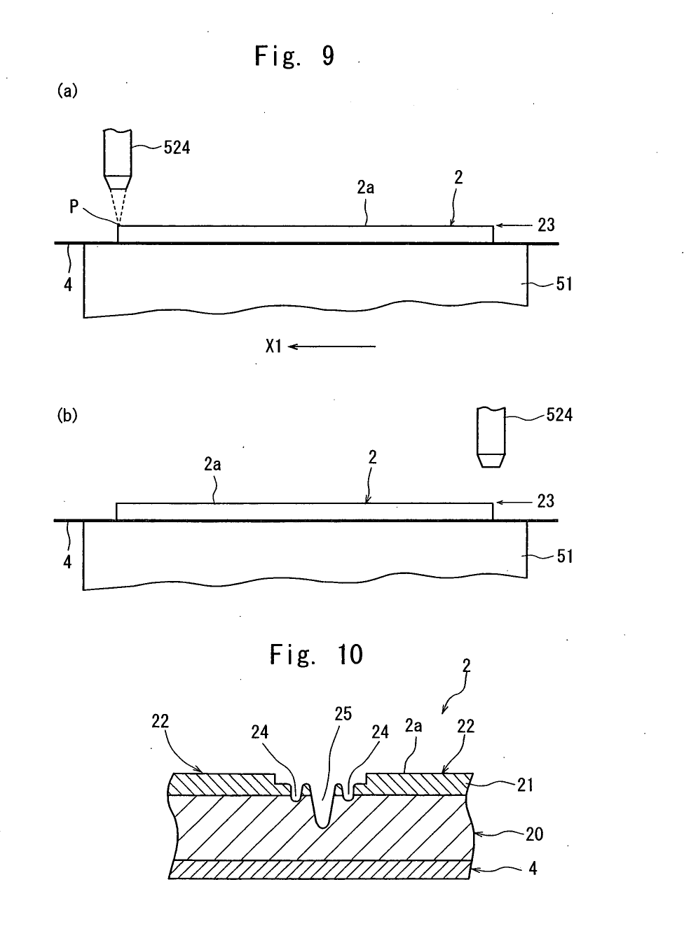

A detailed description will be subsequently given of the above second groove forming step with reference to FIGS. 9(a) and 9(b) and FIG. 10.

The chuck table 51 holding the optical device wafer 2, which has been subjected to the above first groove forming step, is moved to the laser beam application area where the condenser 524 of the laser beam application means 52 for applying a laser beam is located to bring a predetermined street 23 to a position right below the condenser 524, and the center position between the above two grooves 24 and 24 formed in the street 23 is so adjusted as to become the application position of a laser beam applied from the condenser 524. At this point, as shown in FIG. 9(a), the optical device wafer 2 is positioned such that one end (left end in FIG. 9(a)) of the street 23 is located right below the condenser 524. The chuck table 51, that is, the optical device wafer 2 is then moved in the direction indicated by the arrow X1 in FIG. 9(a) at a predetermined processing-feed rate while a second pulse laser beam is applied from the condenser 524 of the laser beam application means 52. The pulse energy of the second laser beam applied in this second groove forming step is set greater than the pulse energy of the first laser beam in the above first groove forming step. When the other end (right end in FIG. 9(b)) of the street 23 reaches a position right below the condenser 524 as shown in FIG. 9(b), the application of the pulse laser beam is suspended and the movement of the chuck table 51, that is, the optical device wafer 2 is stopped. In this second groove forming step, the focusing point P of the second pulse laser beam is set to a position near the front surface of the street 23.

By carrying out the above second groove forming step, in the street 23 of the optical device wafer 2, a dividing groove 25 having a predetermined depth is formed in the laminate layer 21 and the substrate 20 at the center position between the two grooves 24 and 24 for preventing the flaking of a layer, as shown in FIG. 10. The depth of this dividing groove 25 may be about 100 μm when the thickness of the optical device wafer 2 is about 400 μm. Since the laminate layer 21 of the street 23 is divided by the two grooves 24 and 24 for preventing the flaking of a layer, even if the laminate layer 21 flakes off by the application of the second pulse laser beam in the second groove forming step, the flaking does not affect the outer sides of the two grooves 24 and 24 for preventing the flaking of a layer, that is, the sides of devices 22. Therefore, the pulse energy of the second pulse laser beam can be increased, and the dividing groove 25 can be formed to a desired depth that facilitates division of the wafer. The above second groove forming step is carried out on all the streets 23 of the optical device wafer 2, which has been subjected to the first groove forming step.

The above second groove forming step is carried out under the following processing conditions, for example.
Light source of laser beam: YVO4 laser or YAG laser
Wavelength: 355 nm
Repetition frequency: 50 kHz
Pulse energy: 120 μJ
Focusing spot diameter: 10 μm
Processing-feed rate: 100 mm/sec

The optical device wafer 2, which has been subjected to the first groove forming step and the second groove forming step, is carried to the subsequent dividing step. In the dividing step, as the dividing grooves 25 formed in the streets 23 of the optical device wafer 2 are formed deep enough to facilitate division of the wafer, the optical device wafer 2 can be easily divided by mechanical breaking.

The present invention which is applied to the optical device wafer has been described above. When the present invention is applied to the laser processing of a semiconductor wafer having a plurality of circuits that are composed of a laminate layer laminated on the front surface of a substrate along streets, the same function and effect can be obtained.

What is claimed is:

1. A method of laser processing a wafer having a plurality of devices that are composed of a laminate layer laminated on the front surface of a substrate, along a plurality of streets for sectioning the devices, comprising:
a first groove forming step for applying a first laser beam having absorptivity for the wafer along the streets of the wafer at predetermined intervals to form two grooves for preventing the flaking of a layer, which divide the laminate layer; and
a second groove forming step for applying a second laser beam having absorptivity for the wafer to the center between the two grooves for preventing the flaking of a layer, which have been formed along the streets of the wafer by the first groove forming step, along the streets of the wafer to form a dividing groove having a predetermined depth in the laminate layer and the substrate.
